(19) United States
(12) Patent Application Publication
(10) Pub. No.: US 2024/0013155 A1
(43) Pub. Date: Jan. 11, 2024

(54) FORCASTING TOOL

(71) Applicant: ADP, Inc., Roseland, NJ (US)

(72) Inventor: Ramsay COLE, Roxbury, CT (US)

(21) Appl. No.: 17/857,446

(22) Filed: Jul. 5, 2022

(51) Int. Cl. G06Q 10/10; G06F 30/20

(52) U.S. Cl. CPC G06Q 10/1053; G06F 30/20

(57) ABSTRACT

The present disclosure relates generally to a forecasting tool and, more particularly, to a method, system and computer program product for forecasting (e.g., predicting) and reporting future environmental (e.g., climate) changes. A computer-implemented method includes: retrieving, by a computer system, employment data; aggregating, by the computer system, the employment data; injecting the aggregated employment data and climate components into a climate modeling application which analyzes the aggregated employment data and the climate components to generate a predictive climate model; and obtaining a report related to the predictive climate model.

### TECHNICAL FIELD

The present disclosure relates generally to a forecasting tool and, more particularly, to a method, system and computer program product for forecasting (e.g., predicting) and reporting future environmental (e.g., climate) changes.

### BACKGROUND

Scientists both public and private spend billions of dollars and countless hours leveraging legacy time series climate data and systems to generate varied and often inaccurate climate models. Also, gathering and analyzing multiple sets of data and using such information to model future changes may be challenging using traditional sources. For example, it is possible to monitor climate at certain locations at certain points in time, but limited available information makes it difficult to accurately predict future climate change. More specifically, traditional methods of monitoring climate do not account for many factors that may affect the climate in the future.

Illustratively, traditional data collection may use static or backward looking data; however, this data can become very stale and does not account for demographic or population changes or how future occurrences may affect the climate. For example seven (7) variable components are used in current climate modeling: (i) atmosphere; (ii) ocean; (iii) sea ice; (iv) land surface; (v) marine biogeochemistry; (vi) ice sheets; and (vii) coupling between the components. However, the models do not account for changes related to future events or other granular data which may affect the environment.

In other words, current tools, leverage a static/point in time data, which may result in a skewed result when predicting or modeling future climate changes, as the data may not be predictive of future consumption, pollution, etc. And although leveraging point in time environmental data may be useful, it needs to be understood that using such data may be too late as the climate has already changed and it may not be possible to reverse course. Accordingly, better methods must be created and deployed to more accurately predict climate change so that policy makers can become more informed and preemptive in their decision making, i.e., data can be better leveraged before drought and/or drastic temperature change has occurred.

### SUMMARY

In a first aspect of the present disclosure, a computer-implemented method includes: retrieving, by a computer system, employment data; aggregating, by the computer system, the employment data; injecting the aggregated employment data and climate components into a climate modeling application which analyzes the aggregated employment data and the climate components to generate a predictive climate model; and obtaining a report related to the predictive climate model.

In another aspect of the present disclosure, there is a computer program a computer program product comprising one or more computer readable storage media having program instructions collectively stored on the one or more computer readable storage media. The program instructions are executable to: obtain payroll data; map the payroll data to at least an industry type; assign a score to the mapped payroll data, with a higher score having a higher environmental impact than a lower score; and inject the scored and mapped payroll data into a climate modeling application which analyzes the scored and mapped payroll data with climate components to generate a predictive climate model.

In a further aspect of the present disclosure, there is a system comprising a processor, a computer readable memory, one or more computer readable storage media, and program instructions collectively stored on the one or more computer readable storage media. The program instructions are executable to: collect mapped employment data related to industry type and location; collect climate sustainability data; collect an environmental score associated with the mapped employment data; inject the mapped and scored employment data with the climate sustainability data into a climate model application; analyze the mapped and scored employment data with the climate sustainability data with environmental components to generate a future looking climate model; and provide a remediation solution based on the future looking climate model.

### BRIEF DESCRIPTION OF THE DRAWINGS

Aspects of the present disclosure are described in the detailed description which follows, in reference to the noted plurality of drawings by way of non-limiting examples of exemplary embodiments of the present disclosure.

FIG. 1 is an illustrative architecture of a computing system implemented in embodiments of the present disclosure.

FIG. 2 shows an exemplary cloud computing environment in accordance with aspects of the present disclosure.

FIG. 3 shows a block diagram in accordance with aspects of the present disclosure.

FIG. 4 depicts an exemplary flow for a process in accordance with aspects of the present disclosure.

### DETAILED DESCRIPTION OF ASPECTS OF THE INVENTION

The present disclosure relates generally to a forecasting tool and, more particularly, to a method, system and computer program product for forecasting (e.g., predicting or modeling) and reporting future environmental (e.g., climate) changes, and providing remedial solutions. More specifically and in accordance with aspects of the present disclosure, the method, system and computer program product leverage real-time employment data, which can be extrapolated (e.g., trending data), to predict or model climate changes to the environment (i.e., impacts on the environment due to changes in the climate). Advantageously, aspects of the present disclosure provide improved methods to create and deploy more accurate climate models so that such models can be leveraged proactively and preemptively to drive policy decisions from both private and public perspectives. In this way, such models can be leveraged before drought and/or drastic changes have occurred in order for policy makers or others to take preemptive remedial actions.

In more specific embodiments, the method, system and computer program product use real-time payroll and demographic data along with other datasets (e.g., satellite, instrumental and environmental records to name a few) to model and forecast environmental (e.g., climate) changes. For example, the tools provided herein may aggregate data regarding a plurality of factors associated with employment information and geographic region, perform analysis on the data using machine learning and/or neural network computing to construct a predictive model, and populate a database with other datasets to generate a more accurate predictive climate model. This predictive climate model can be used to generate reports showing the consequences (e.g., carbon footprint or other greenhouse gas emissions) of certain employment data and which can be used to generate or provide remedial solutions.

The employment information may include type of industry, employment type within the industry, etc., and each of any combination of factors may be scored based on a climate impact. For example, a coal miner may have a higher score than a teacher or office worker, as coal mining may affect the climate more than teaching. In addition, in implementation, the payroll data may be extrapolated to include trending payroll and demographic data by geography, industry or other micro or macro indicators to predict or forecast an impact such trending employment data may have on the environment. In these ways, the solution becomes intelligent and can identify which regions may need immediate or future remedial actions, e.g., environmental solutions.

By implementing the tools provided herein, it is now possible to accurately model climate change using, in the least, payroll data, to provide enhanced planning solutions on both a micro and macro level. This will allow governments and private industry to efficiently make policy decisions based on predicted environmental impacts of employment, industry needs, etc. For example, it may now be possible to consider, curb and reverse climate change before it happens by implementing policy changes based on the more accurate predictive climate models, including leveraging such information for a trending quality of life score for government planning or residential/commercial real estate site selection strategies. That is, utilizing such data sets allows intentional planning, providing communities with the required resourcing to proactively reduce negative environmental impacts that may be caused from certain industries and/or employment.

Accordingly, the tools described herein provide a technical solution to a problem by predicting climate change prior to them occurring, and proactively and preemptively allowing for the planning of such environment impacts on both a micro and macro level. Generally, this technical solution can be accomplished by, amongst other features as described herein, modelling climate impacts using anonymized and aggregated time series payroll data that is (i) more granular, (ii) timely, and (ii) uses real-time data compared to legacy data sets (such as surveys). And by aggregating this data, it is possible to generate a clear picture of all the factors that affect climate change and predict or model such changes and provide solutions to correct for any negative impacts to the environment. Thus, implementations of the invention provide an improvement in the technical field of climate change forecasting by providing a technical solution to the problem of inaccurate modeling and, in cases, results in a reactive remediation solution.

Implementations of the present disclosure may be a computer system, a computer-implemented method, and/or a computer program product. The computer program product is not a transitory signal per se, and may include a computer readable storage medium (or media) having computer readable program instructions thereon for causing a processor to carry out aspects of the present disclosure. As described herein, the computer readable storage medium (or media) is a tangible storage medium (or media). It should also be understood by those of skill in the art that the terms media and medium are used interchangeable for both a plural and singular instance.

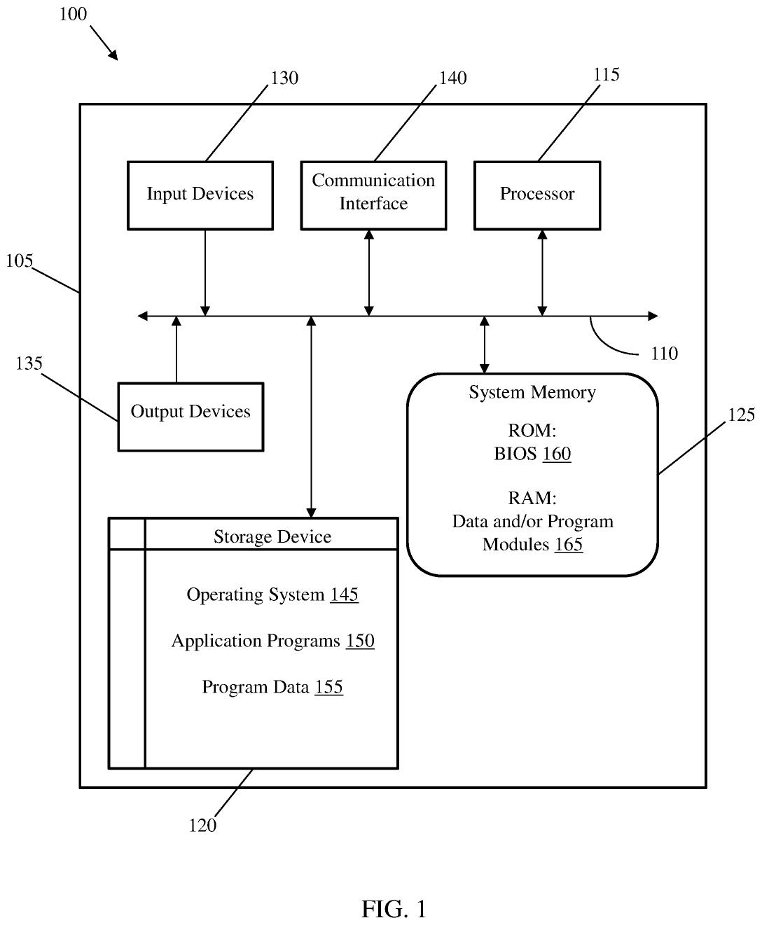

FIG. 1 is an illustrative architecture of a computing system 100 implemented in embodiments of the present disclosure. The computing system 100 is only one example of a suitable computing system and is not intended to suggest any limitation as to the scope of use or functionality of the disclosure. Also, computing system 100 should not be interpreted as having any dependency or requirement relating to any one or combination of components illustrated in computing system 100.

As shown in FIG. 1, computing system 100 includes a computing device 105. The computing device 105 can be resident on a network infrastructure such as within a cloud environment, or may be a separate independent computing device (e.g., a computing device of a third party service provider). The computing device 105 may include a bus 110, a processor 115, a storage device 120, a system memory (hardware device) 125, one or more input devices 130, one or more output devices 135, and a communication interface 140.

The bus 110 permits communication among the components of computing device 105. For example, bus 110 may be any of several types of bus structures including a memory bus or memory controller, a peripheral bus, and a local bus using any of a variety of bus architectures to provide one or more wired or wireless communication links or paths for transferring data and/or power to, from, or between various other components of computing device 105.

The processor 115 may be one or more processors or microprocessors that include any processing circuitry operative to interpret and execute computer readable program instructions, such as program instructions for controlling the operation and performance of one or more of the various other components of computing device 105. For example, processor 115 enables the computing device 105 to forecast changes to the climate using real-time information such as payroll data, optionally in conjunction with other type of data such as data obtained from third party sources, e.g., governments, municipalities, open sources, etc. This other data may include census data, emission data for vehicles, power generation and transmission, electric car tax credits, alternative energy tax credits, home solar credits, sensor data, weather reports, etc., in addition to the components used in current climate models such as global patterns in the ocean and atmosphere, records of the types of weather that occurred under similar patterns in the past as obtained through sensors, satellite data, environmental records, etc. As described in more detail herein, this data may be used initially as training data for machine learning or neural network computing systems.

In embodiments, real-time payroll data may include, for example, (i) types of industry, (ii) number of employees in each of the different industries, (iii) geographic locations of the industry, (iv) trending employment data (e.g., population migrations, employee needs, etc.), (v) commute distances (e.g., calculating by using the location of employment and residence of employee), (vi) types of employment within the industry (e.g., administrative, etc.), etc. The processor 115 can provide trending data by extrapolating the employment information from current and past trends.

The processor 115 can also assign a score to any combination of data based on an amount of carbon or other greenhouse gas emissions associated with each of the different factors. For example, an industry associated with higher emissions, i.e., burning of coal, oil or gas to name a few, will be assigned a higher score than an industry associated with lower emissions. As another example, a person with a longer commute may be assigned a higher score than a person with a shorter or no commute. The scores can also be broken down to sub-scores based on geography, job type within the industry, industry (e.g., gas, oil, etc.), etc. And scores can be adjusted based on different job types, different computes, different industries, etc., within different geographic locations. By using this information in climate modeling, it is now possible to provide more accurate and granular models which will allow policy makers the ability to implement remedial solutions, preemptively and proactively, on best ways to curb or reverse environmental impacts based on this real-time granular information.

In embodiments, processor 115 interprets and executes the processes, steps, functions, and/or operations of the present disclosure, which may be operatively implemented by the computer readable program instructions. In embodiments, processor 115 may receive input signals from one or more input devices 130 and/or drive output signals through one or more output devices 135. The input devices 130 may be, for example, one or more mechanisms that permit an operator to input information to computing device 105 such as a keyboard, touch sensitive user interface (UI), etc. The one or more output devices 135 may include one or more mechanisms that output information to an operator, e.g., any display device, printer, etc.

The storage device 120 may include removable/non-removable, volatile/non-volatile computer readable media (or medium), such as, but not limited to, non-transitory media such as magnetic and/or optical recording media and their corresponding drives. The drives and their associated computer readable media provide for storage of computer readable program instructions, data structures, program modules and other data for operation of computing device 105 in accordance with the different aspects of the present disclosure. In embodiments, storage device 120 may store operating system 145, application programs 150, and program data 155 in accordance with aspects of the present disclosure.

The system memory 125 may include one or more storage mediums, including for example, non-transitory media such as flash memory, permanent memory such as read-only memory (“ROM”), semi-permanent memory such as random access memory (“RAM”), any other suitable type of storage component, or any combination thereof. In some embodiments, an input/output system 160 (BIOS) including the basic routines that help to transfer information between the various other components of computing device 105, such as during start-up, may be stored in the ROM. Additionally, data and/or program modules 165, such as at least a portion of operating system 145, application programs 150, and/or program data 155, that are accessible to and/or presently being operated on by processor 115 may be contained in the RAM.

The communication interface 140 may include any transceiver-like mechanism (e.g., a network interface, a network adapter, a modem, or combinations thereof) that enables computing device 105 to communicate with remote devices or systems, such as a mobile device or other computing devices such as, for example, a server in a networked environment, e.g., cloud environment. For example, computing device 105 may be connected to remote devices or systems via one or more local area networks (LAN) and/or one or more wide area networks (WAN) using communication interface 140.

As discussed herein, computing system 100 may be configured to provide more accurate climate models using granular, real-time data, e.g., payroll data. In particular, computing device 105 may perform tasks (e.g., process, steps, methods and/or functionality) in response to processor 115 executing program instructions contained in a computer readable medium, such as system memory 125. The program instructions may be read into system memory 125 from another computer readable medium, such as data storage device 120, or from another device via the communication interface 140 or server within or outside of a cloud environment. In embodiments, an operator may interact with computing device 105 via the one or more input devices 130 and/or the one or more output devices 135 to facilitate performance of the tasks and/or realize the end results of such tasks in accordance with aspects of the present disclosure. In additional or alternative embodiments, hardwired circuitry may be used in place of or in combination with the program instructions to implement the tasks, e.g., steps, methods and/or functionality, consistent with the different aspects of the present disclosure. Thus, the steps, methods and/or functionality disclosed herein can be implemented in any combination of hardware circuitry and software.

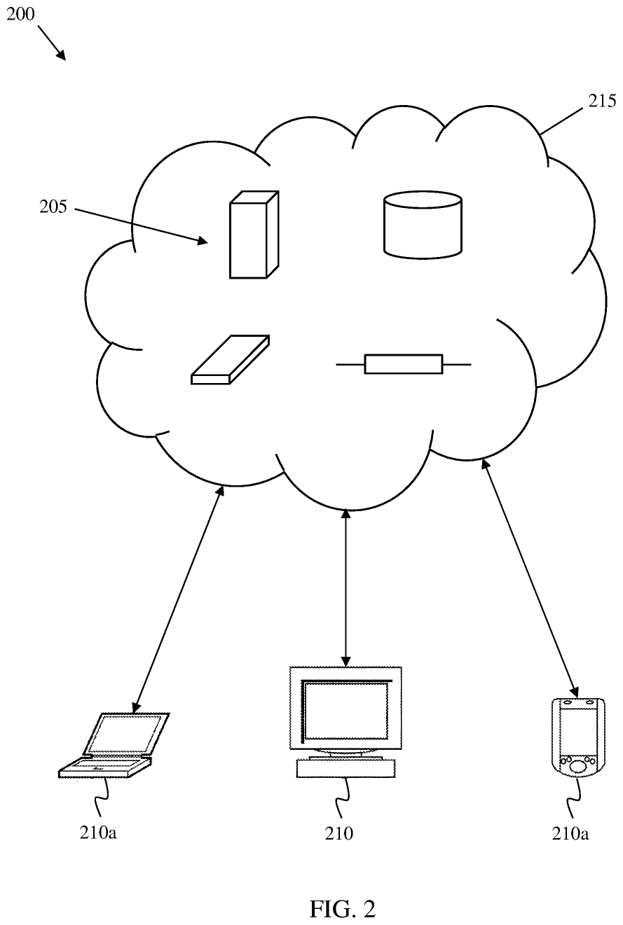

FIG. 2 shows an exemplary cloud computing environment 200 in accordance with aspects of the disclosure. Cloud computing is a computing model that enables convenient, on-demand network access to a shared pool of configurable computing resources, e.g., networks, servers, processing, storage, applications, and services, which can be provisioned and released rapidly, dynamically, and with minimal management efforts and/or interaction with the service provider. In embodiments, one or more aspects, functions and/or processes described herein may be performed and/or provided via cloud computing environment 200.

As depicted in FIG. 2, cloud computing environment 200 includes cloud resources 205 that are made available to client devices 210 via a network 215, such as the Internet. Cloud resources 205 can include a variety of hardware and/or software computing resources, such as servers, databases, storage, networks, applications, and platforms. Cloud resources 205 may be on a single network or a distributed network. Cloud resources 205 may be distributed across multiple cloud computing systems and/or individual network enabled computing devices. Client devices 210 may comprise any suitable type of network-enabled computing device, such as servers, desktop computers, laptop computers, handheld computers (e.g., smartphones, tablet computers), set top boxes, and network-enabled hard drives. Cloud resources 205 are typically provided and maintained by a service provider so that a client does not need to maintain resources on a local client device 210. In embodiments, cloud resources 205 may include one or more computing system 100 of FIG. 1 that is specifically adapted to perform one or more of the functions and/or processes described herein.

Cloud computing environment 200 may be configured such that cloud resources 205 provide computing resources to client devices 210 through a variety of service models, such as Software as a Service (SaaS), Platforms as a service (PaaS), Infrastructure as a Service (IaaS), and/or any other cloud service models. Cloud resources 205 may be configured, in some cases, to provide multiple service models to a client device 210. For example, cloud resources 205 can provide both SaaS and IaaS to a client device 210. Cloud resources 205 may be configured, in some cases, to provide different service models to different client devices 210. For example, cloud resources 205 can provide SaaS to a first client device 210 and PaaS to a second client device 210.

Cloud computing environment 200 may be configured such that cloud resources 205 provide computing resources to client devices 210 through a variety of deployment models, such as public, private, community, hybrid, and/or any other cloud deployment model. Cloud resources 205 may be configured, in some cases, to support multiple deployment models. For example, cloud resources 205 can provide one set of computing resources through a public deployment model and another set of computing resources through a private deployment model.

In embodiments, software and/or hardware that performs one or more of the aspects, functions and/or processes described herein may be accessed and/or utilized by a client (e.g., an enterprise or an end user) as one or more of a SaaS, PaaS and IaaS model in one or more of a private, community, public, and hybrid cloud. Moreover, although this disclosure includes a description of cloud computing, the systems and methods described herein are not limited to cloud computing and instead can be implemented on any suitable computing environment.

Cloud resources 205 may be configured to provide a variety of functionality that involves user interaction. Accordingly, a user interface (UI) can be provided for communicating with cloud resources 205 and/or performing tasks associated with cloud resources 205. The UI can be accessed via a client device 210 in communication with cloud resources 205. The UI can be configured to operate in a variety of client modes, including a fat client mode, a thin client mode, or a hybrid client mode, depending on the storage and processing capabilities of cloud resources 205 and/or client device 210. Therefore, a UI can be implemented as a standalone application operating at the client device in some embodiments. In other embodiments, a web browser-based portal can be used to provide the UI. Any other configuration to access cloud resources 205 can also be used in various implementations.

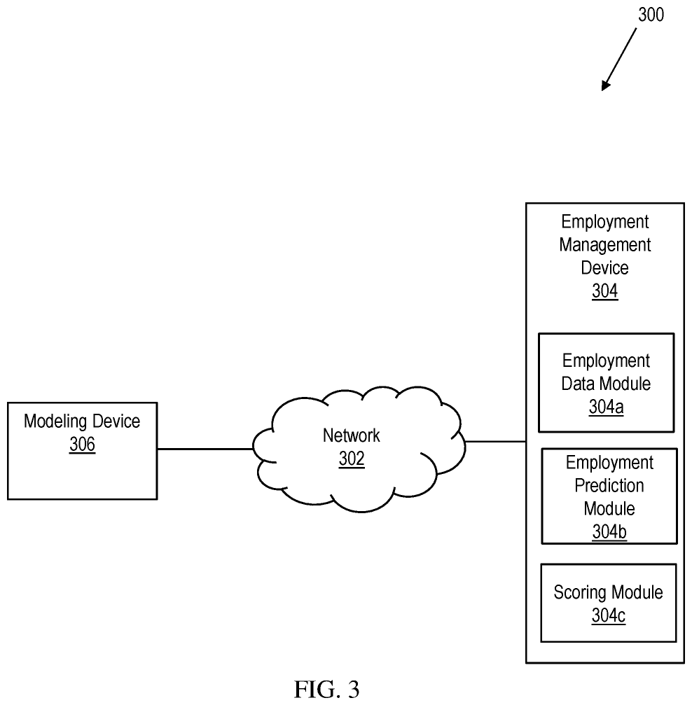

FIG. 3 shows a block diagram in accordance with aspects of the present disclosure. More specifically, FIG. 3 shows a functional block diagram 300 that illustrates functionality of aspects of the present disclosure. The functional block diagram 300 of FIG. 3 includes a network 302 enabling communication between an employment management device 304 and a modeling device 306. The network 302 may be representative of the cloud infrastructure of FIG. 2. The employment management device 304 and modeling device 306 may each comprise one or more program modules such as program modules 165 described with respect to FIG. 1. The devices 304, 306 may include additional or fewer modules than those shown in FIG. 3. In embodiments, separate modules may be integrated into a single module. Additionally, or alternatively, a single module may be implemented as multiple modules. Moreover, the quantity of devices and/or networks in the environment is not limited to what is shown in FIG. 3. In practice, the environment may include additional devices and/or networks; fewer devices and/or networks; different devices and/or networks; or differently arranged devices and/or networks than illustrated in FIG. 3.

In embodiments, the employment management device 304 comprises employment data module 304a, employment prediction module 304b and scoring module 304c, each of which may comprise one or more program modules such as program modules 165 described with respect to FIG. 1. In embodiments, the employment data module 304a may include employment data collected (i.e., aggregated) from payroll data received from third-party sources. The third-party sources may include governmental sources or private sources through an opt-out or opt-in process. A government source may be the social security administration, internal revenue service, unemployment administration, or other government agencies that collect information. The private source may be a payroll company such as ADP Inc. The payroll data may be collected (i.e., obtained) from a payroll module (i.e., data sources), which is maintained by the third-party source. In embodiments, collection of data may include any type of employment data.

Advantageously, the employment data may be collected on a regular or real-time basis, e.g., shorter time periods of time. The employment data will provide enhancements over current tools which rely on static/point in time data sets; that is, payroll data that is collected at shorter periods of time will better reflect climate concerns such as migration of residents, employment resource changes, changes in industry, changes in demographics (i.e., white/blue collar employment shifts that may be due to changes in costs of living in a location, changes in industry, etc.).

The employment data may be real-time, granular data, including e.g., (i) types of industry, (ii) number of employees in each of the different industries, (iii) geographic locations of the industry, (iv) location of employment; (v) employee residence; (vi) type of job (e.g., clerical, manufacturing, services, mining, etc.) within the industry, etc. In embodiments, the payroll data may exclude such personal information as social security number, name, etc.; instead, the payroll data may include anonymized employment information that could be used to model climate changes. Data anonymization is the process of protecting private or sensitive information by erasing or encrypting identifiers that connect an individual.

As should be understood, each of the different granular real-time factors may be associated with a carbon footprint or, e.g., other emissions entering into the atmosphere. For example, oil, gas and coal industries would have a higher environmental footprint (impact) compared to teaching, IT or administrative or service industries. The number of employees in each of the different industries can also be indicative of a certain environmental footprint. For example, a large number of employees in the mining industry can be indicative of a larger environmental footprint at a certain geographical location. The location of employment and employee residence may be indicative of a certain commute distance, which also has a direct environmental impact on emissions. For example, a worker with a longer commute time with no access to mass transportation may have a larger environmental footprint than a worker living in a city and has access to mass transportation. This data may be trained upon using machine learning or neural networking computer to further refine the association between employment data, e.g., payroll data, and climate change or how such employment data may affect the environment as described in more detail herein.

In embodiments, the employment prediction module 304b is configured to use the employment data to predict certain trends in employment and industry needs by geographic region. This prediction may be based on extrapolation of employment data including migration patterns and/or trends in population growth, the need for different or more employment types within certain industries, or which employers in which industry within a certain geographic region have different needs, e.g., needs of the employee based on job title, job type, etc. In embodiments, trends may also be based on additional examples including industry employment resource capabilities and changes such as increases or decreases in resources, e.g., construction workers, mining, stockpile of commodities, etc., in particular industries or location. Accordingly, the employment prediction module 304b may be used to determine trending patterns based on industry, geography, employment type, commute type and time, and/or other important factors.

In this way, the employment prediction module 304b may aggregate and iteratively analyze historical and present data against historical changes and current needs based on, for example, employment data, to extrapolate and construct improved predictive models using machine learning and/or neural network computing. And the employment prediction module 304b may provide predictions based on geographic regions by extrapolating trends from training data which includes the payroll information (i.e., the historical sampling and resulting infrastructure changes). Also, in embodiments, the employment prediction module 304b may layer other legacy data with trending employment data and demographic data obtained from payroll data or other open sources, and for a geographic region provide a prediction of industry growth indicating future resource needs and environmental impacts. Thus, the trending points can be used to further refine the models by understanding on both a micro and macro level and within certain geographic locations, whether there will be an increase or decrease in environmental footprints based on patterns within industry (expanding vs. contracting), types of jobs, etc.

The scoring module 304c is configured to provide a weighting to data. For example, the scoring module 304c may be used to provide different scores to each of the different data from the employment data module 304a and employment prediction module 304b. For example, the scoring module 304c may have an increased confidence that a certain industry will have a greater impact on climate based on indications in payroll data and score it accordingly. In other words, payroll increases may be a strong indicator of population increase based on a certain industry presence, and, hence, the industry may be weighted more heavily. The scoring module 304c may also take into consideration the location and cost of raw materials, machinery needed to perform certain tasks within the industry and how such machinery or transport of raw materials may impact climate, e.g., mining of fossil fuels or ores may be considered a higher pollutant source than an administrative task, hence leading to a higher score.

The data from the employment data module 304a, employment prediction module 304b and the scoring module 304c may be transmitted/sent to the modeling device 306. In embodiments, the modeling device 306 may be third party device with known modeling software that uses the above noted seven (7) components when modeling climate changes, in addition to now using the injected additional data described herein to provide a more predictive model. Accordingly, the modeling device 306 may use this data with other legacy data and the components used in traditional modeling to formulate a more accurate climate model. For example, considering employment data, it is now possible to use real-time granular data to forecast current and future emissions based on geography, industry, employment type, commute time, etc., in addition to other data such as emission data for vehicles and power generation and transmission, electric car tax credits, alternative energy tax credits, home solar credits, sensor data, etc.

It should be understood by those of ordinary skill in the art that the payroll data and how it is associated with climate change, e.g., emissions by industry, person, type of job, etc., can be used as quality training data for the machine learning and neural network computing as provided herein. The training data refers to the initial data that is used to develop a machine learning model, from which the model creates and refines its rules. The quality of the payroll data and its associated correlated consequences on climate change can be refined based on trending data and other data from legacy or open sources from third parties. The payroll data can be mined from the business decisions and activities that are already known or which are being refined. Also, as should be understood by those of skill in the art, the payroll data is already clean and formatted consistently for training purposes. In addition, the remediation data and its associated consequences on climate change can be used as training data for further refinement of remediation efforts as described herein. That is, by using an interactive process, it is possible to train on and refine remediation efforts based on the different combinations of variables that may be used with respect to payroll data. For example, the training data may be the initial dataset used to train machine learning algorithms, and the models create and refine their rules using this data.

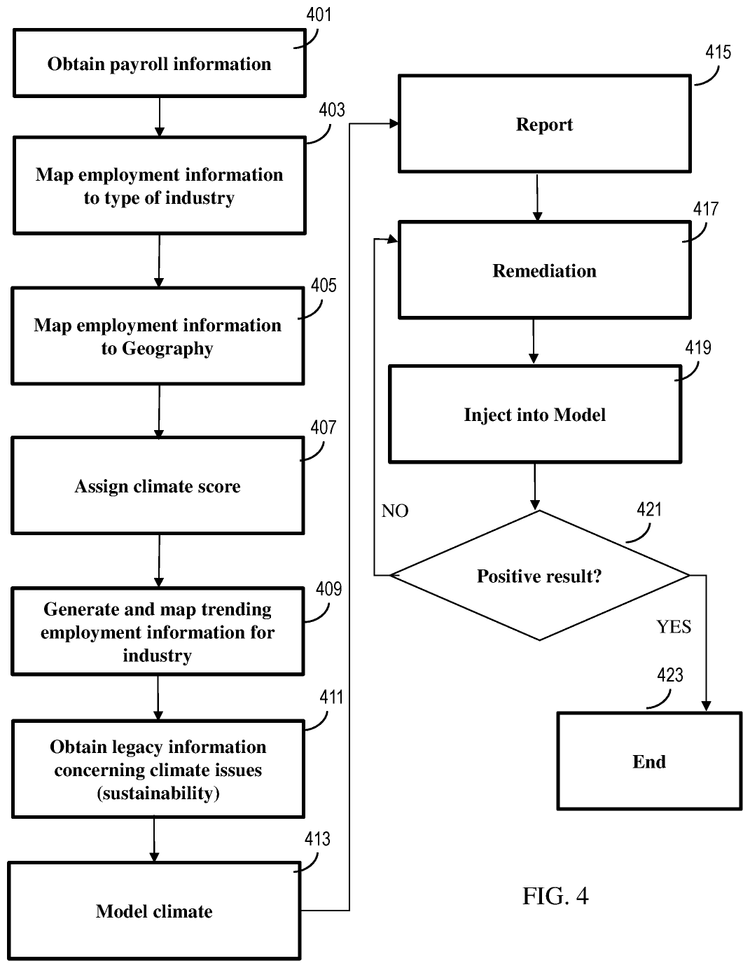

FIG. 4 depicts an exemplary flow for a process in accordance with aspects of the present disclosure. The exemplary flow can be illustrative of a system, a method, and/or a computer program product and related functionality implemented on the computing system of FIG. 1, in accordance with aspects of the present disclosure. The computer program product may include computer readable program instructions stored on computer readable storage medium (or media). The computer readable storage medium may include the one or more storage medium as described with regard to FIG. 1, e.g., non-transitory media, a tangible device, etc. The method, and/or computer program product implementing the flow of FIG. 4 can be downloaded to respective computing/processing devices, e.g., computing system of FIG. 1 as already described herein, or implemented on a cloud infrastructure as described with regard to FIG. 2. Accordingly, the processes associated with each flow of the present disclosure can be implemented by special purpose hardware-based systems that perform the specified functions or acts or carry out combinations of special purpose hardware and computer instructions.

At step 401, the processes obtain payroll information. This payroll information may include, home address, work address, type of employment (administrative, manufacturing, services, mining, etc., work arrangement (work at home or commute), type of industry, etc.

At step 403, the processes map the employment information to a type of industry. By way of example, the mapping may include mapping of all job types associated with each industry. At step 405, the processes map the employment information to geographical locations.

At step 407, the processes assign a score to the employment information, i.e., geographical locations, industry type, type of employment (e.g., job types associated with each industry), etc. In embodiments, a higher score will be indicative of a higher weight assigned to the particular data, e.g., industry, etc., which can be used in the climate model. In a non-limiting illustrative embodiment, the score may be based on a scale of 0-100, with 100 having the greatest impact on the climate or environment.

In embodiments, the score can be generated with any combination of the data, e.g., a smaller commute may lower a score for a particular type of employment; whereas a longer commute for the same type of employment may raise the score. As another example, an industry in a particular location that has implemented cutting edge technologies or through local regulatory mandates has a lower environmental footprint may be given a lower score than a same industry in another location that does not implement the same technology or is subjected to the same regulatory mandates. In this way, the score may be adjusted and can be different depending on many different factors.

At step 409, the processes provide a trending of the employment data and map the trending information to industry type and/or employer and/or geography. The trending information may be head count or other information, e.g., growth of industry, need for particular industry at a particular location based on supply/demand information, etc. This trending information can be obtained by extrapolating the payroll information over time.

At step 411, the processes obtain legacy information concerning climate issues (sustainability). For example, this legacy information may include electric car tax credits, alternative energy tax credits, home solar credits, census data, current emission data, demographic information, etc. In addition, legacy information may include weather data (e.g., rain, ice, snow, etc.), which may be collected from weather organizations such as the national weather service. Other legacy data may include census data collected from the United States Census Bureau. The census data may include population by location, employment levels, districting, demographics, housing characteristics, etc. The legacy information may also include data that provides links or associates certain industries to certain emissions or certain types of pollution, as obtained from open sources and governmental institutions such as the Environmental Protection Agency (EPA). The legacy information may be mapped to the payroll data.

At step 413, the processes inject the information obtained in steps 401-411 into a climate model to generate a more granular and predictive climate model. For example, as the climate model now includes granular data which is weighted based on an environmental impact (e.g., carbon footprint), and which includes trending data for employment, a more accurate, predictive climate model can be generated and used for remediation and policy purposes. Also, by using the trending data of industry, geographic location and related jobs, it is possible to determine how such data will impact the environment before it actually happens. This impact can be even more accurately reflected by weighting certain factors more heavily than others. For example, a higher weight (score) can be provided to a manufacturing or mining job than an administrative position.

At step 415, the processes generate a report associated with the climate model. The generated report(s) may make use of the machine learning model by extrapolating trends in the employment data to determine indicators that predict future climate impacts from employment data. The generated report(s) may provide explanations of why the impact of employment data may have an impact on the environment. For example, the report may a forecast of climate change based on certain industries or trending employment information, any of which will provide a much more granular narrative of future climate change and what factors may be affecting such environmental impacts. By way of illustration, if more employees in a geographic region are telecommuting and are in a service industry, e.g., banking, then the generated report may state a predicted climate impact based on an increase of employment in such industry, etc.

At step 417, the reports may be used to create a more predictive solution to climate change, i.e., generate remediation solutions. For example, the reports can be used for creating remediation efforts such as increasing mass transportation, providing tax credits for energy efficient and/or low carbon technologies, moving an industry to certain locations, or other micro/macro environment remediation efforts, etc., including those related to payroll or employment.

At step 419, the remediation solution can be reinjected into the climate model. At step 421, a determination is made as to whether the suggested the remediation solution will have a desired effect, e.g., positive effect on climate models. If so, the processes end at step 423. If not or for other reasons, the processes can revert back to step 417 for generating other remediate solutions. The new remediate solutions can then be injected into the model for further analysis. In this way, an iterative process can be implemented to refine any of the remediate actions.

### Illustrative Example Use Case

Jennifer Smith works in the field of data monetization within the human resources industry. Jennifer Smith does not have a commute to work. John Smith, on the other hand, works in the mining industry as a miner. John also has a long commute to work, with no public transportation available. In this situation, John Smith will have a much higher score (e.g., weighting) assigned to his environmental impact (e.g., carbon footprint) compared to Jennifer Smith. This information may be obtained from the employment data module shown in FIG. 3.

The method, system and computer program product may calculate trending data indicating that the mining industry is forecasted to increase in its headcount based on number of employees hired over the last predetermined period of time in combination, for example, with the mines current output and the expected needed for ore in future products. The information obtained may be mapped to industry and location.

With this information now available and additional information concerning, for example, census data and other data that may have a known impact on the environment, the method, system and computer program product may inject such information into a climate model application. The climate model application can use the information in combination with the conventional seven (7) components to generate a forward looking climate model. This model can then be used to generate remediation actions. These actions can be changes to the permit policies for mining, changes to regulations for mining, adjustments to headcount and time of working hours, etc.

Accordingly, implementing of the present invention will create a forward looking predictive model which can be leveraged in a granular form using the above noted employment datasets layered into other data for climate predictions. In this way, the present invention provides modelling using machine learning and/or neural network computing to predict climate change and based on these determinations, create reports and generate remedial solutions in a preemptive and proactive manner. The machine learning techniques can predict or model climate changes using a plurality of data associated with the employment data and geographic region, amongst other data described herein. And by aggregating the data, it is possible to generate a clear picture of all the factors that affect climate change and predict or model such climate change. Thus, implementations of the invention provide an improvement in the technical field of climate change forecasting by providing a technical solution to the problem of inaccurate climate modeling.

The foregoing examples have been provided merely for the purpose of explanation and are in no way to be construed as limiting of the present disclosure. While aspects of the present disclosure have been described with reference to an exemplary embodiment, it is understood that the words which have been used herein are words of description and illustration, rather than words of limitation. Changes may be made, within the purview of the appended claims, as presently stated and as amended, without departing from the scope and spirit of the present disclosure in its aspects. Although aspects of the present disclosure have been described herein with reference to particular means, materials and embodiments, the present disclosure is not intended to be limited to the particulars disclosed herein; rather, the present disclosure extends to all functionally equivalent structures, methods and uses, such as are within the scope of the appended claims.

What is claimed is:

1. A computer-implemented method, comprising:
retrieving, by a computer system, employment data;
aggregating, by the computer system, the employment data;
injecting the aggregated employment data and climate components into a climate modeling application which analyzes the aggregated employment data and the climate components to generate a predictive climate model; and
obtaining a report related to the predictive climate model.

2. The computer-implemented method of claim 1, wherein the aggregated employment data comprises at least a type of employment, type of industry, location of employment, and residence of an employee.

3. The computer-implemented method of claim 2, further comprising mapping the aggregated employment data to the location of employment and industry type.

4. The computer-implemented method of claim 3, further comprising generating trending employment data from the aggregated employment data, and injecting the trending employment data into the climate modeling application with the climate components to provide the predictive climate model.

5. The computer-implemented method of claim 4, wherein the trending employment data comprises head count for industry type and location.

6. The computer-implemented method of claim 4, further comprising generating a score, by the computer system, based on an environmental impact for at least one type of the employment data.

7. The computer-implemented method of claim 6, wherein the at least one type of the employment data comprises employment type, industry and location.

8. The computer-implemented method of claim 6, further comprising obtaining legacy information concerning climate issues and injecting the legacy information into the climate modeling application with the climate components and the aggregated employment data.

9. The computer-implemented method of claim 6, further comprising generating a remediation solution based on the predictive climate model using the employment data.

10. The computer-implemented method of claim 9, further comprising reinjecting the remediation solution into the climate modeling application to reanalyze the employment data and the climate components with the remediation solution to provide an updated predictive climate model.

11. A computer program product comprising one or more computer readable storage media having program instructions collectively stored on the one or more computer readable storage media, the program instructions executable to:
obtain payroll data;
map the payroll data to at least an industry type;
assign a score to the mapped payroll data, with a higher score having a higher environmental impact than a lower score; and
inject the scored and mapped payroll data into a climate modeling application which analyzes the scored and mapped payroll data with climate components to generate a predictive climate model.

12. The computer program product of claim 11, wherein the payroll data comprises time series payroll data that is anonymized and aggregated.

13. The computer program product of claim 11, wherein the score is broken into sub-scores.

14. The computer program product of claim 11, further comprising providing trending information of the payroll data comprising at least job type by headcount and injecting the trending information into the climate modeling application.

15. The computer program product of claim 14, wherein the payroll data comprises at least a type of employment, type of industry, location of employment, and residence of an employee.

16. The computer program product of claim 15, further comprising generating a remediation solution based on the climate model using the payroll data.

17. The computer program product of claim 16, further comprising reinjecting the remediation solution into the climate modeling application to provide an updated predictive climate model.

18. A system comprising:
a processor, a computer readable memory, one or more computer readable storage media, and program instructions collectively stored on the one or more computer readable storage media, the program instructions executable to:
collect mapped employment data related to industry type and location;
collect climate sustainability data;
collect an environmental score associated with the mapped employment data;
inject the mapped and scored employment data with the climate sustainability data into a climate model application;
analyze the mapped and scored employment data with the climate sustainability data with environmental components to generate a future looking climate model; and
provide a remediation solution based on the future looking climate model.

19. The system of claim 18, wherein the remediation solution is reinjected into the climate model application to determine effects of the remediation solution program on climate change.

20. The system of claim 18, wherein the employment date is aggregated time series information comprises at least type of industry, location and employment type with the industry.
